(19) United States
(12) Patent Application Publication
(10) Pub. No.: US 2023/0238335 A1
(43) Pub. Date: Jul. 27, 2023

(54) SEMICONDUCTOR CHIP INCLUDING A CHIP GUARD

(71) Applicant: SK hynix Inc., Icheon-si Gyeonggi-do (KR)

(72) Inventor: Won Sun SEO, Icheon-si Gyeonggi-do (KR)

(73) Assignee: SK hynix Inc., Icheon-si Gyeonggi-do (KR)

(21) Appl. No.: 17/850,149

(22) Filed: Jun. 27, 2022

(30) Foreign Application Priority Data
Jan. 21, 2022 (KR) 10-2022-0009561

(51) Int. Cl. H01L 23/00; H01L 23/58

(52) U.S. Cl. CPC H01L 23/562; H01L 23/585

(57) ABSTRACT

A semiconductor chip includes an integrated circuit disposed in a device region, and a chip guard disposed in a chip sealing region that is an outer portion of the device region. The chip guard includes a first metal layer disposed over a substrate, an interlayer insulating layer disposed on the first metal layer, a second metal layer disposed on the interlayer insulating layer, and a barrier pattern extending in a direction towards the substrate from the second metal layer through the interlayer insulating layer. The barrier pattern is disposed to be spaced apart from the first metal layer.

### CROSS-REFERENCE TO RELATED APPLICATIONS

The present application claims priority under 35 U.S.C 119(a) to Korean Application No. 10-2022-0009561, filed on Jan. 21, 2022, which is incorporated herein by reference in its entirety.

### BACKGROUND

### 1. Technical Field

The present disclosure generally relates to a semiconductor chip including a chip guard.

### 2. Related Art

Through a semiconductor integration process, it is possible to manufacture a plurality of semiconductor chips separated from each other by a scribe lane region on a wafer. Each of the plurality of semiconductor chips may include a protection structure in an outer region of the chip to protect integrated circuits therein. As an example of the protection structure, a guard ring may prevent external moisture from penetrating into the integrated circuits via the outer region of the chip.

As a planar shape, the guard ring may be disposed to surround the integrated circuits at a boundary region with the scribe lane region. In addition, as a cross-sectional shape, the guard ring may be formed in a multilayer structure including a plurality of metal layers disposed on a substrate and a via metal layer connecting the plurality of metal layers.

### SUMMARY

A semiconductor device according to an embodiment of the present disclosure may include an integrated circuit disposed in a device region, and a chip guard disposed in a chip sealing region that is an outer portion of the device region. The chip guard may include a first metal layer disposed over a substrate, an interlayer insulating layer disposed on the first metal layer, a second metal layer disposed on the interlayer insulating layer, and a barrier pattern extending in a direction towards the substrate from the second metal layer through the interlayer insulating layer. The barrier pattern may be disposed to be spaced apart from the first metal layer.

A semiconductor device according to another embodiment of the present disclosure may include an integrated circuit disposed in a device region, and a chip guard disposed in a chip sealing region that is an outer portion of the device region. The chip guard may include a first metal layer disposed over a substrate, an interlayer insulating layer disposed on the first metal layer, a second metal layer disposed on the interlayer insulating layer, a contact pattern connecting the first and second metal layers to each other in the interlayer insulating layer, an insulating protection structure disposed on the second metal layer, a barrier trench penetrating the insulating protection structure and formed in a lateral direction of the second metal layer, and a metal barrier layer disposed along a sidewall surface of the barrier trench. A bottom surface of the barrier trench may be disposed to be spaced apart from an upper surface of the second metal layer.

A semiconductor device according to further another embodiment of the present disclosure may include an integrated circuit disposed in a device region, and a chip guard disposed in a chip sealing region that is an outer portion of the device region. The chip guard may include a plurality of metal layers disposed over a substrate, at least one interlayer insulating layer disposed between the plurality of metal layers, and a barrier pattern extending toward the substrate from at least one metal layer among the plurality of metal layers. The barrier pattern may be disposed to be spaced apart from the remaining metal layers, except for the at least one metal layer among the plurality of metal layers, in a lateral direction.

### BRIEF DESCRIPTION OF THE DRAWINGS

FIG. 1 is a schematic plan view illustrating a wafer including a plurality of semiconductor chips according to an embodiment of the present disclosure.

FIG. 2A is a schematic cross-sectional view illustrating a boundary region between a device region and a chip sealing region of a semiconductor chip according to an embodiment of the present disclosure.

FIG. 2B is an enlarged view of region ‘A’ of FIG. 2A.

FIG. 3 is a schematic cross-sectional view illustrating a boundary region between a device region and a chip sealing region of a semiconductor chip according to another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. Variations from the shapes of the illustrations as a result, for example, of manufacturing techniques and/or tolerances, are to be expected. Thus, the embodiments should not be construed as limited to the particular shapes of regions illustrated herein but may be to include deviations in shapes that result, for example, from manufacturing. In the drawings, lengths and sizes of layers and regions may be exaggerated for clarity. It will be understood that when an element, structure, pattern, or layer etc., is referred to as being “on,” “connected to” or “coupled to” another element, structure, pattern, or layer etc., it can be directly on, connected or coupled to the other element, structure, pattern, or layer etc., or intervening elements, structures, patterns, or layers etc., may be present. In contrast, when an element, structure, pattern, or layer etc., is referred to as being “directly on,” “directly connected to” or “directly coupled to” another element, structure, pattern, or layer etc., there are no intervening elements, structures, patterns, or layers etc., present. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

In this specification, a semiconductor chip may mean that a semiconductor substrate on which an electronic circuit is integrated has a shape that is distinguished from each other in the form of a chip. Accordingly, the semiconductor chip may be used to encompass not only a form in which a semiconductor substrate is cut into a chip form but also a state in which separate semiconductor chip regions are formed on the semiconductor substrate even before being cut into the chip shape.

The semiconductor chip may refer to a memory chip in which memory integrated circuits such as dynamic random access memory (DRAM) circuits, static random access memory (SRAM) circuits, NAND-type flash memory circuits, NOR-type flash memory circuits, magnetic random access memory (MRAM) circuits, resistive random access memory (ReRAM) circuits, ferroelectric random access memory (FeRAM) circuits, or phase change random access memory (PcRAM) are integrated, logic dies or ASIC chips in which logic circuits are integrated in a semiconductor substrate. Meanwhile, the semiconductor chip may be referred to as a semiconductor die.

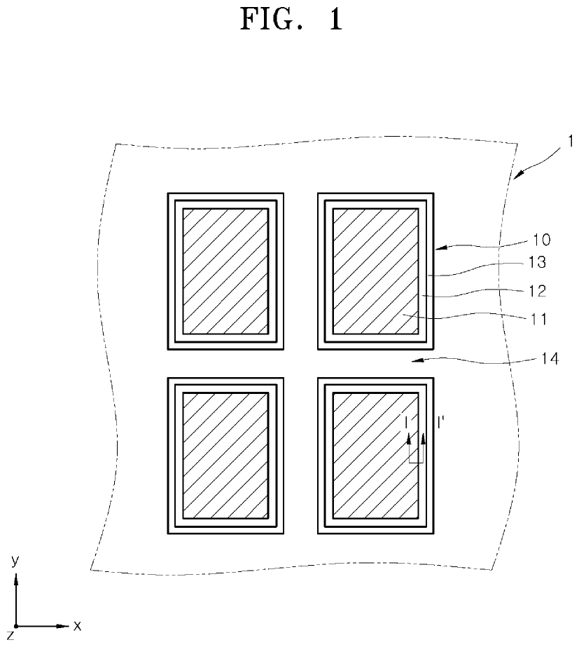

FIG. 1 is a schematic plan view illustrating a wafer 1 including a plurality of semiconductor chips according to an embodiment of the present disclosure. The wafer 1 may include a plurality of semiconductor chips 10 and a scribe lane region 14 between the plurality of semiconductor chips 10. Each of the plurality of semiconductor chips 10 may include a device region 11, a chip sealing region 12, and a chip boundary region 13.

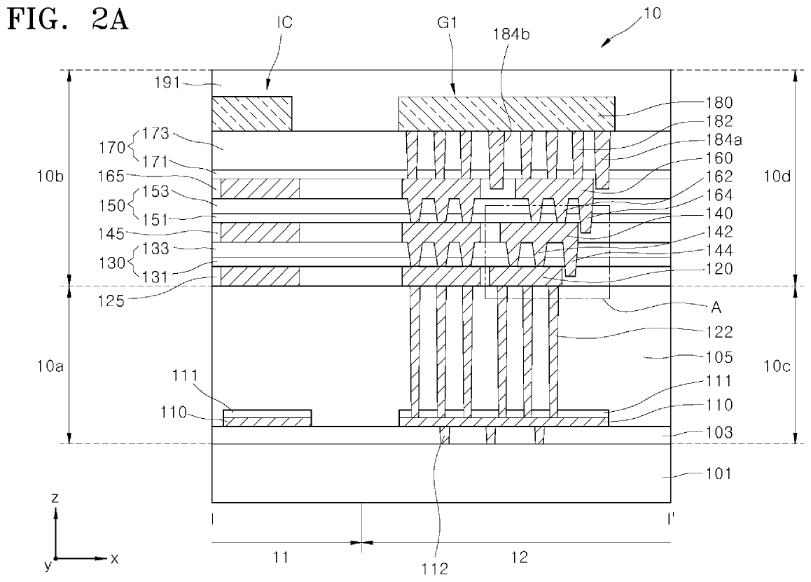

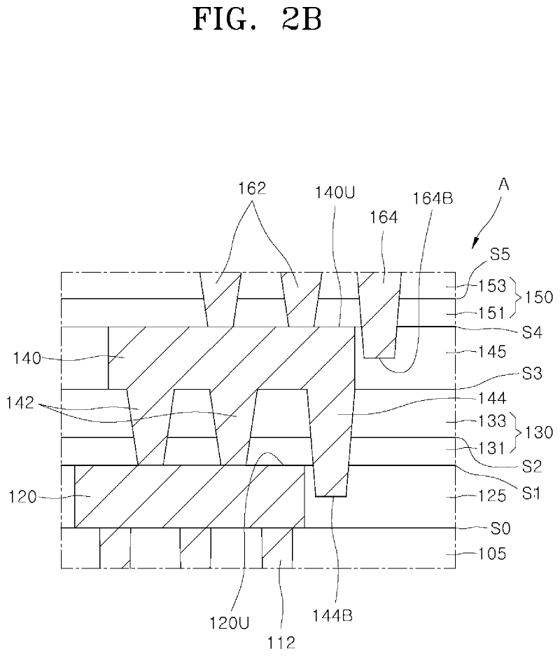

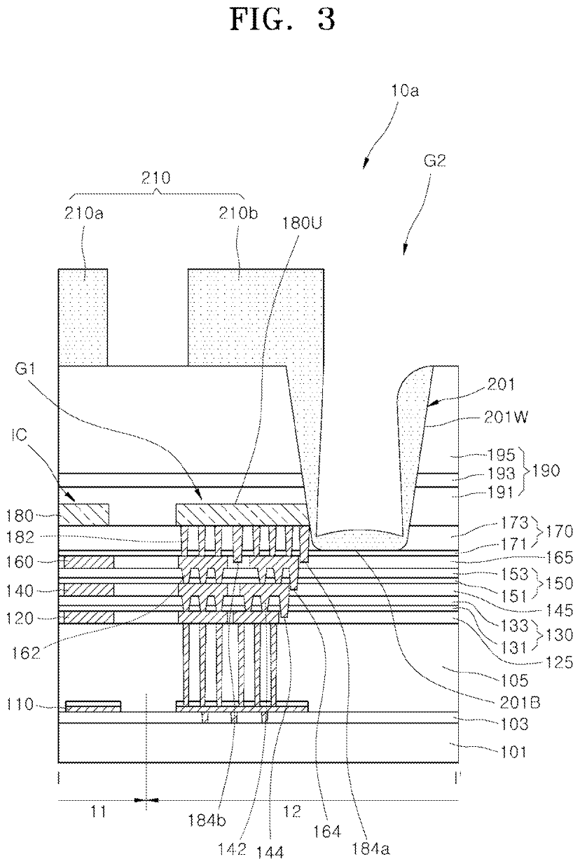

The semiconductor chip 10 may include integrated circuits in the device region 11. The integrated circuits may include various electronic circuits involved in the operation of the semiconductor chip 10. The semiconductor chip 10 may include a chip guard that protects the integrated circuits in the chip sealing region 12, which is an outer portion of the device region 11. The chip guard will be described in detail with reference to FIGS. 2A, 2B, and 3 below. The chip boundary region 13 of the semiconductor chip 10 may be an outermost region of the chip, forming a boundary with the scribe lane region 14.

FIG. 2A is a schematic cross-sectional view illustrating a boundary region between a device region and a chip sealing region of a semiconductor chip according to an embodiment of the present disclosure. Specifically, FIG. 2A is a cross-sectional view taken along line I-I′ of the semiconductor chip 10 of FIG. 1. FIG. 2B is an enlarged view of region ‘A’ of FIG. 2A.

Referring to FIG. 2A, the semiconductor chip 10 may include an integrated circuit IC in the device region 11 and a chip guard G1 in the chip sealing region 12. The integrated circuit IC may include a lower integrated structure 10a and an upper integrated structure 10b that are sequentially stacked on a substrate 101. The chip guard G1 may include a lower guard structure 10c and an upper guard structure 10d sequentially disposed on the substrate 101. The substrate 101 may include a semiconductor material. Although not shown, the substrate 101 may include a well region doped with an n-type or p-type dopant.

The lower integrated structure 10a and the lower guard structure 10c may be formed during a front-end process of forming a semiconductor device on the substrate 101. The upper integrated structure 10b and the upper guard structure 10d may be formed during a back-end process of forming a metal wiring of the semiconductor device. The lower integrated structure 10a and the upper integrated structure 10b may have various electrical circuit patterns according to the design of the semiconductor chip. In an embodiment, the lower guard structure 10c and the upper guard structure 10d may be a stack structure for protecting the integrated circuit (IC).

Referring to FIG. 2A, the lower integrated structure 10a disposed in the device region 11 forming a boundary with the chip sealing region 12 may include a lower metal layer 110, a hard mask layer 111, and first and second lower insulating layers 103 and 105. The lower metal layer 110 may include, for example, tungsten (W). In an embodiment, when the semiconductor chip 10 is a memory device, the lower metal layer 110 may constitute a bit line. The hard mask layer 111 may be disposed on the lower metal layer 110, and may include, for example, nitride.

The first lower insulating layer 103 may be disposed between the substrate 101 and the lower metal layer 110. The second lower insulating layer 105 may be disposed to cover the lower metal layer 110 and the hard mask layer 111 on the first lower insulating layer 103. Each of the first and second lower insulating layers 103 and 105 may include an insulating material having excellent step coverage and gap fill characteristics. As an example, each of the first and second lower insulating layers 103 and 105 may include an oxide material such as tetraethyl orthosilicate (TEOS) or borophosphosilicate glass (BPSG). In other embodiments, each of the first and second lower insulating layers 103 and 105 may include an insulating material having step coverage and gap fill characteristics.

Referring to FIG. 2A, in the device region 11 bordering the chip sealing region 12, the upper integrated structure 10b may include first to fourth metal layers 120, 140, 160, and 180, first to third planarization insulating layers 125, 145, and 165, first to third interlayer insulating layers 130, 150, and 170, and a passivation layer 191. The first to fourth metal layers 120, 140, 160, and 180 may function as metal wirings in the semiconductor chip 10.

The first metal layer 120 may be disposed on the second lower insulating layer 105. The first metal layer 120 may include, for example, copper (Cu). The first planarization insulating layer 125 may be disposed to surround a side surface of the first metal layer 120. The first planarization insulating layer 125 may include an insulating material having a low dielectric constant in order to reduce coupling capacitance occurring between metal wires. As an example, the first planarization insulating layer 125 may include an oxide material including silicon (Si), carbon (C), oxygen (O), and hydrogen (H). In an embodiment, the first planarization insulating layer 125 may include an insulating material having a dielectric constant in order to reduce coupling capacitance occurring between metal wires. An upper surface of the first planarization insulating layer 125 may be positioned at the same level as an upper surface of the first metal layer 120. The first planarization insulating layer 125 may be disposed to extend from the device region 11 to the chip sealing region 12.

The first interlayer insulating layer 130 may be disposed on the first metal layer 120 and the first planarization insulating layer 125. The first interlayer insulating layer 130 may include a first metal capping layer 131 and a first intermetallic insulating layer 133. The first metal capping layer 131 may be disposed on upper surfaces of the first metal layer 120 and the first planarization insulating layer 125. In an embodiment, the first metal capping layer 131 may be disposed to cover the first metal layer 120 to serve to protect the first metal layer 120. An interface between the first metal capping layer 131 and the first planarization insulating layer 125 may extend from the device region 11 to the chip sealing region 12.

The first metal capping layer 131 may be made of a material different from that of the first planarization insulating layer 125. The first planarization insulating layer 125 may include an oxide material having a low dielectric constant, and the first metal capping layer 131 may include nitride. The first metal capping layer 131 may include, for example, nitride including silicon (Si), carbon (C), and nitrogen (N). In an embodiment, the first planarization insulating layer 125 may include an oxide material having a dielectric constant.

The first intermetallic insulating layer 133 may be disposed on the first metal capping layer 131. The first intermetallic insulating layer 133 and the first metal capping layer 131 may be disposed to form an interface, and the interface may extend from the device region 11 to the chip sealing region 12.

In an embodiment, the first intermetallic insulating layer 133 may include an insulating material having a low dielectric constant in order to reduce coupling capacitance occurring between metal wires. As an example, the first intermetallic insulating layer 133 may include an oxide material including silicon (Si), carbon (C), oxygen (O), and hydrogen (H). In an embodiment, the first intermetallic insulating layer 133 may be made of the same material as the first planarization insulating layer 125. In an embodiment, the first intermetallic insulating layer 133 may be made of a material different from that of the first metal capping layer 131 including nitride. In an embodiment, the first intermetallic insulating layer 133 may include an insulating material having a dielectric constant.

The second metal layer 140 may be disposed on the first interlayer insulating layer 130. A configuration of the second metal layer 140 may be substantially the same as that of the first metal layer 120. The second planarization insulating layer 145 surrounding a side surface of the second metal layer 140 may be disposed on the first interlayer insulating layer 130. A configuration of the second planarization insulating layer 145 may be substantially the same as that of the first planarization insulating layer 125.

The second interlayer insulating layer 150 may be disposed on the second metal layer 140 and the second planarization insulating layer 145. The second interlayer insulating layer 150 may include a second metal capping layer 151 and a second intermetallic insulating layer 153. The second metal capping layer 151 may be disposed on upper surfaces of the second metal layer 140 and the second planarization insulating layer 145. An interface between the second metal capping layer 151 and the second planarization insulating layer 145 and an interface between the second metal capping layer 151 and the second intermetallic insulating layer 153 may extend from the device region 11 to the chip sealing region 12.

A configuration of the second interlayer insulating layer 150 may be substantially the same as that of the first interlayer insulating layer 130. As an example, the second metal capping layer 151 may be made of a material different from those of the second planarization insulating layer 145 and the second intermetallic insulating layer 153. The second planarization insulating layer 145 and the second intermetallic insulating layer 153 may be made of substantially the same material.

The third metal layer 160 may be disposed on the second interlayer insulating layer 150. A configuration of the third metal layer 160 may be substantially the same as that of the first metal layer 120. The third planarization insulating layer 165 surrounding a side surface of the third metal layer 160 may be disposed on the second interlayer insulating layer 150. A configuration of the third planarization insulating layer 165 may be substantially the same as that of the first planarization insulating layer 125.

The third interlayer insulating layer 170 may be disposed on the third metal layer 160 and the third planarization insulating layer 165. The third interlayer insulating layer 170 may include a third metal capping layer 171 and a third intermetallic insulating layer 173. The third metal capping layer 171 may be disposed on upper surfaces of the third metal layer 160 and the third planarization insulating layer 165. An interface between the third metal capping layer 171 and the third planarization insulating layer 165 and an interface between the third metal capping layer 171 and the third intermetallic insulating layer 173 may extend from the device region 11 to the chip sealing region 12.

A configuration of the third interlayer insulating layer 170 may be substantially the same as that of the first interlayer insulating layer 130. As an example, the third metal capping layer 171 may be made of a material different from that of the third planarization insulating layer 165 and the third intermetallic insulating layer 173. The third planarization insulating layer 165 and the third intermetallic insulating layer 173 may be made of substantially the material.

In some embodiments, when the third interlayer insulating layer 170 is disposed between the third metal layer 160 and the uppermost metal layer, for example, in this case the fourth metal layer 180, the third intermetallic insulating layer 173 of the third interlayer insulating layer 170 may be made of a material different from those of the first and second intermetallic insulating layers 133 and 153 of the first and second interlayer insulating layers 130 and 150, respectively. While, in an embodiment, the first and second intermetallic insulating layers 133 and 153 include an oxide material having a low dielectric constant, the third intermetallic insulating layer 173 may include, in an embodiment, an oxide material having excellent step coverage and gap fill characteristics. As an example, the third intermetallic insulating layer 173 may include tetraethyl orthosilicate (TEOS).

Referring to FIG. 2A, the fourth metal layer 180 may be disposed on the third interlayer insulating layer 170. In an embodiment, the fourth metal layer 180 may be disposed as the uppermost metal layer in the semiconductor chip 10. The fourth metal layer 180 may be made of a material different from those of the first to third metal layers 120, 140, and 160. As an example, the first to third metal layers 120, 140, and 160 may include copper (Cu), while the fourth metal layer 180 may include aluminum (Al).

The passivation layer 191 may be disposed to cover the fourth metal layer 180 on the third interlayer insulating layer 170. The passivation layer 191 may include, for example, high density plasma (HDP) oxide.

Although not shown in FIG. 2A, the lower integrated structure 10a of the integrated circuit IC may include a first contact pattern layer for electrically connecting the lower metal layer 110 to the substrate 101, and a second contact pattern layer for electrically connecting the first metal layer 120 to the lower metal layer 110. In addition, the upper integrated structure 10b of the integrated circuit IC may include contact vias for electrically connecting two metal layers selected from the first to fourth metal layers 120, 140, 160, and 180 to each other.

Although, in FIG. 2A, the upper integrated structure 10b includes four metal layers, but is not limited thereto, and the upper integrated structure 10b may include various numbers of metal layers. However, the metal layer disposed as the uppermost layer may include aluminum (Al) and the remaining metal layers may include copper (Cu). Although not shown in FIG. 2A, the lower integrated structure 10b may further include another metal layer in addition to the lower metal layer 110. Whether to add the metal layer may be determined according to device design of the semiconductor chip 10.

Referring to FIG. 2A, the chip guard G1 may be disposed in the chip sealing region 12. Referring to FIG. 2A along with FIG. 1, the chip guard G1 may be disposed in the chip sealing region 12 to surround the integrated circuit IC of the device region 11. In an embodiment, the chip guard G1 may be a structure for protecting the integrated circuit IC. The chip guard G1 may include the lower guard structure 10c and the upper guard structure 10d that are sequentially disposed over the substrate 101.

The lower guard structure 10c may be formed with the lower integrated structure 10a disposed in the device region 11 when the front-end process is performed. Similarly, the upper guard structure 10d may be formed with the upper integrated structure 10b disposed in the device region 11 when the back-end process is performed.

Referring to FIG. 2A, the lower guard structure 10c may include the lower metal layer 110 and first and second lower contact patterns 112 and 122. The first lower contact pattern 112 may connect the lower metal layer 110 to the substrate 101. The second lower contact pattern 122 may connect the lower metal layer 110 to the first metal layer 120. In an embodiment, each of the first and second lower contact patterns 112 and 122 may include tungsten (W).

In addition, the lower guard structure 10c may include the hard mask layer 111 and the first and second lower insulating layers 103 and 105. The hard mask layer 111 may be disposed on the lower metal layer 110. The first lower insulating layer 103 may be disposed between the substrate 101 and the lower metal layer 110. The second lower insulating layer 105 may be disposed to cover the lower metal layer 110 and the hard mask layer 111 on the first lower insulating layer 103.

Referring to FIG. 2A, the upper guard structure 10d may include the first metal layer 120 disposed on the second lower insulating layer 105, the second metal layer 140 disposed over the first metal layer 120, the third metal layer 160 disposed over the second metal layer 140, and the fourth metal layer 180 disposed over the third metal layer. In an embodiment, the fourth metal layer 180 may be an uppermost metal layer.

In addition, the upper guard structure 10d may include the first interlayer insulating layer 130 disposed between the first metal layer 120 and the second metal layer 140, the second interlayer insulating layer 150 disposed between the second metal layer 140 and the third metal layer 160, the third interlayer insulating layer 170 disposed between the third metal layer 160 and the fourth metal layer 180.

The first interlayer insulating layer 130 may include the first metal capping layer 131 and the first intermetallic insulating layer 133 made of different materials. The second interlayer insulating layer 150 may include the second metal capping layer 151 and the second intermetallic insulating layer 153 made of different materials. The third interlayer insulating layer 170 may include the third metal capping layer 171 and the third intermetallic insulating layer 173 made of different materials.

The upper guard structure 10d may include a first contact pattern 142 that is disposed inside the first interlayer insulating layer 130 and connects the first metal layer 120 and the second metal layer 140. In addition, the upper guard structure 10d may include a second contact pattern 162 that is disposed inside the second interlayer insulating layer 150 and connects the second metal layer 140 and the third metal layer 160. In addition, the upper guard structure 10d may include a third contact pattern 182 that is disposed inside the third interlayer insulating layer 170 and connects the third metal layer 160 and the fourth metal layer 180.

In an embodiment, each of the first to third contact patterns 142, 162, and 182 may be, for example, a line pattern or a plug pattern. In an embodiment, each of the first to third contact patterns 142, 162, and 182 may include, for example, copper (Cu) or tungsten (W). In an embodiment, when each of the first to third metal layers 120, 140, and 160 includes copper (Cu), and the fourth metal layer 180 includes aluminum (Al), each of the first and second contact patterns 142 and 162 may include copper (Cu), and the third contact pattern 182 may include tungsten (W). In an embodiment, the second metal layer 140 and the first contact pattern 142 may be formed together by a damascene process. Similarly, the third metal layer 160 and the second contact pattern 162 may be formed together by a damascene process.

Referring to FIG. 2A, the upper guard structure 10d may include the first planarization insulating layer 125 disposed between the second lower insulating layer 105 and the first metal capping layer 131. The first planarization insulating layer 125 may be disposed to surround the side surface of the first metal layer 120. In addition, the upper guard structure 10d may include the second planarization insulating layer 145 disposed between the first intermetallic insulating layer 133 and the second metal capping layer 151 and surrounding the side surface of the second metal layer 140. In addition, the upper guard structure 10d may include the third planarization insulating layer 165 disposed between the second intermetallic insulating layer 153 and the third metal capping layer 171 and surrounding the side surface of the third metal layer 160.

As described above, the chip guard G1 may include a metal structure stacked on the substrate. In an embodiment, the metal structure may be disposed to cross the plurality of insulating layers in the z-direction perpendicular to the substrate 101, so that moisture inside or outside the chip sealing region 12 may be prevented or mitigated from flowing into the device region 11 via the plurality of insulating layers. The first lower contact pattern 112, the lower metal layer 110, the second lower contact pattern 122, the first metal layer 120, the first contact pattern 142, the second metal layer 140, the second contact pattern 162, the third metal layer 160, the third contact pattern 182, and the fourth metal layer 180 may be connected to each other along the z-direction over the substrate 101.

Meanwhile, referring to FIG. 2A, the chip guard G1 according to an embodiment of the present disclosure may include first to third barrier patterns 144, 164, 184a, and 184b extending in a substrate 101 direction from the second to fourth metal layers 140, 160, and 180. In an embodiment, third barrier patterns 184a and 184b may constitute the third barrier pattern 184. In an embodiment, each of the first to third barrier patterns 144, 164, 184a, and 184b may include copper (Cu) or tungsten (W). In an embodiment, each of the first to third barrier patterns 144, 164, 184a, and 184b may be a line pattern or a plug pattern.

In an embodiment, when each of the first to third metal layers 120, 140, and 160 includes copper (Cu) and the fourth metal layer 180 includes aluminum (Al), each of the first and second barrier patterns 144 and 164 may include copper (Cu) and the third barrier patterns 184a and 184b may include tungsten (W).

Referring to FIGS. 2A and 2B together, the first barrier pattern 144 may extend from the second metal layer 140 through the first interlayer insulating layer 130 to reach the inside of the first planarization insulating layer 125. In an embodiment, the first barrier pattern 144 may be disposed farther from the device region 11 than the first contact pattern 142. That is, the first barrier pattern 144 may be disposed closer to the chip boundary region (13 of FIG. 1) than the first contact pattern 142.

The first barrier pattern 144 may be disposed to be spaced apart from the first metal layer 120 in a lateral direction (i.e., direction perpendicular to the z-direction). In an embodiment, referring to FIG. 2B, a bottom surface 144B of the first barrier pattern 144 may be disposed below (i.e., closer to the substrate 101) than the upper surface 120U of the first metal layer 120.

Referring to FIG. 2B, the first planarization insulating layer 125 and the first metal capping layer 131 may form an interface S1. In addition, the first metal capping layer 131 and the first intermetallic insulating layer 133 may form an interface S2. As described above, in an embodiment, because the first planarization insulating layer 125 and the first metal capping layer 131 are made of different materials and the first metal capping layer 131 and the first intermetallic insulating layer 133 are made of different materials, cracks may occur at the interface S1 and the interface S2 due to stress caused by the difference in coefficient of thermal expansion. For example, in an embodiment, when the first metal capping layer 131 includes a nitride material and each of the first planarization insulating layer 125 and the first intermetallic insulating layer 133 include an oxide material of low dielectric constant, cracks may be generated at the interface S1 and the interface S2 by interlayer stress. In an embodiment, the crack may be generated from the chip sealing region 12 or the chip boundary region (13 in FIG. 1), in which the metal layer has a low density, and may propagate to the device region 11.

Meanwhile, in an embodiment, when the first barrier pattern 144 is not disposed, the first contact pattern 142 may be disposed to cross the interface S2 between the first metal capping layer 131 and the first intermetallic insulating layer 133 to block cracks propagating along the interface S2. However, in an embodiment, it may be difficult for the first contact pattern 142 to block cracks propagating along the interface S1 between the first planarization insulating layer 125 and the first metal capping layer 131.

According to an embodiment of the present disclosure, the first barrier pattern 144 is disposed to cross the interface S1 and the interface S2 from the second metal layer 140 to effectively block cracks propagating through the interface S1 and the interface S2.

In some embodiments other than those shown in the drawings, when the second lower insulating layer 105 and the first planarization insulating layer 125 are made of different materials having a sufficiently large difference in thermal expansion coefficient, the first barrier pattern 144 may extend from the second metal layer 140 through the first interlayer insulating layer 130, through the first planarization insulating layer 125, and into the second lower insulating layer 105. Accordingly, the bottom surface 144B of the first barrier pattern 144 is disposed closer to the substrate 101 than a bottom surface of the first metal layer 120. The bottom surface of the first metal layer 120 is substantially the same level as an interface S0 between the second lower insulating layer 105 and the first planarization insulating layer 125. In an embodiment, the first barrier pattern 144 may block cracks propagating along the interface S0.

Referring to FIGS. 2A and 2B again, the second barrier pattern 164 may extend from the third metal layer 160 through the second interlayer insulating layer 150 to reach the inside of the second planarization insulating layer 145. Accordingly, the second barrier pattern 164 may be disposed to cross an interface S5 between the second metal capping layer 151 and the second intermetallic insulating layer 153 and an interface S4 between the second metal capping layer 151 and the second planarization insulating layer 145. As a result, in an embodiment, the second barrier pattern 164 may effectively block cracks propagating through the interface S4 and the interface S5.

In an embodiment of the present disclosure, the first intermetallic insulating layer 133 and the second planarization insulating layer 145 may be made of substantially the same material. Accordingly, in an embodiment, the possibility that cracks are generated and propagated along an interface S3 between the first intermetallic insulating layer 133 and the second planarization insulating layer 145 may be low. However, in some embodiments, when the intermetallic insulating layer 133 and the second planarization insulating layer 145 are made of different materials having a sufficiently large difference in thermal expansion coefficient, the second barrier pattern 164 may extend from the third metal layer 160 through the second interlayer insulating layer 150 and the second planarization insulating layer 145 to reach the inside of the first intermetallic insulating layer 133. Accordingly, in an embodiment, the second barrier pattern 164 may block cracks propagating along the interface S3 between the first intermetallic insulating layer 133 and the second planarization insulating layer 145.

In an embodiment, the second barrier pattern 164 may be disposed farther from the device region 11 than the second contact pattern 162. That is, the second barrier pattern 164 may be disposed closer to the chip boundary region (13 of FIG. 1) than the second contact pattern 162.

The second barrier pattern 164 may be disposed to be spaced apart from the second metal layer 140 in a lateral direction (i.e., direction perpendicular to the z-direction). In an embodiment, a bottom surface 164B of the second barrier pattern 164 may be disposed below (i.e., closer to the substrate 101) than an upper surface 140U of the second metal layer 140.

Referring to FIG. 2A, the third barrier patterns 184a and 184b may extend from the fourth metal layer 180 through the third interlayer insulating layer 170 to reach the inside of the third planarization insulating layer 165. Accordingly, the third barrier patterns 184a and 184b may be disposed to cross an interface between the third metal capping layer 171 and the third intermetallic insulating layer 173 and an interface between the third metal capping layer 171 and the third planarization insulating layer 165. As a result, in an embodiment, the third barrier patterns 184a and 184b may effectively block cracks propagating through the interface between the third metal capping layer 171 and the third intermetallic insulating layer 173 and the interface between the third metal capping layer 171 and the third planarization insulating layer 165.

The third barrier pattern 184A (i.e., edge pattern) from among the third barrier patterns 184a and 184b may be disposed farther from the device region 11 than the third contact pattern 182 and the third barrier pattern 184b. On the other hand, the third barrier pattern 184b (i.e., center pattern) from among the third barrier patterns 184a and 184b may be disposed closer to the device region 11 than the third barrier pattern 184a. The third barrier pattern 184b may be located between the third contact patterns 182 as shown, for example, in FIG. 2A. In an embodiment, the center pattern or third barrier pattern 184b may be disposed in the regions of the third interlayer insulating layer 170 and the third planarization insulating layer 165 between the third contact patterns 182 to increase the density of the barrier patterns.

Referring to FIG. 2A, the manner in which the first barrier pattern 144, the second barrier pattern 164, and the third barrier pattern 184a (i.e., the edge pattern) are arranged may be such that the barrier pattern disposed higher from the substrate 101 may be disposed farther away from the device region 11 (i.e., disposed closer to the chip boundary region 13).

Meanwhile, in connection with FIG. 2A, although the first to third barrier patterns 144, 164, and 184 respectively extending from the second to fourth metal layers 140, 160, and 180 are disposed, the present disclosure might not be limited thereto. In some embodiments, the barrier pattern may be disposed to extend from one or two metal layers selected from the second to fourth metal layers 140, 160, and 180.

Meanwhile, the first contact pattern 142 and the first barrier pattern 144 may be formed integrally with the second metal layer 140. That is, the first contact pattern 142, the first barrier pattern 144, and the second metal layer 140 may be formed together by one damascene process. As an example, each of the first contact pattern 142, the first barrier pattern 144, and the second metal layer 140 may include copper (Cu). Similarly, the second contact pattern 162 and the second barrier pattern 164 may be formed integrally with the third metal layer 160. As an example, each of the second contact pattern 162, the second barrier pattern 164, and the third metal layer 160 may include copper (Cu). On the other hand, each of the third contact pattern 182 and the third barrier patterns 184a and 184b may be made of a material different from that of the fourth metal layer 180. As an example, each of the third contact pattern 182 and the third barrier patterns 184a and 184b may include tungsten (W), and the fourth metal layer 180 may include aluminum (Al).

As described above, the semiconductor chip according to an embodiment of the present disclosure may include an integrated circuit disposed in a device region and a chip guard disposed in a chip sealing region that is an outer portion of the device region. The chip guard may include one metal layer disposed over a substrate, an interlayer insulating layer disposed over the one metal layer, another metal layer disposed over the interlayer insulating layer, and a barrier pattern penetrating the interlayer insulating layer to extend in the substrate direction and disposed spaced apart from the one metal layer.

In an embodiment, the interlayer insulating layer may include insulating layers of different materials, and the barrier pattern may be disposed to penetrate the interface of the insulating layers of different materials serving as a crack propagation path, so that it is possible to effectively block the crack from propagating along the interface to the device region of the semiconductor chip. As a result, in an embodiment, it is possible to provide a semiconductor chip having a chip guard that performs an effective chip sealing function.

FIG. 3 is a schematic cross-sectional view illustrating a boundary region between a device region and a chip sealing region of a semiconductor chip according to another embodiment of the present disclosure. Specifically, the cross-sectional shape shown in FIG. 3 may correspond to the cross-sectional shape shown when the semiconductor chip 10 of FIG. 1 is taken along line I-I′.

Compared with the semiconductor chip 10 of FIGS. 1, 2A, and 2B, the semiconductor chip 10a of FIG. 3 may further include an insulating protection structure 190 and a redistribution layer 210a disposed over the integrated circuit (IC) in a device region 11. The insulating protection structure 190 may include first to third passivation layers 191, 193, and 195. The first passivation layer 191 may be disposed to cover a fourth metal layer 180 over a third intermetallic insulating layer 173. The second and third passivation layers 193 and 195 may be sequentially disposed on the first passivation layer 191. Each of the first and third passivation layers 191 and 195 may include an oxide material. The second passivation layer 193 may include a nitride material. However, the number and type of material layers constituting the insulating protection structure 190 may vary according to chip design.

The redistribution layer 210a may be a wiring electrically connecting an external connection pad (not shown) installed on a top of the semiconductor chip 10a to an integrated circuit IC during a packaging process of the semiconductor chip 10a. The external connection pad (not shown) of the semiconductor chip 10a may be formed on the redistribution layer 210a to electrically connect the semiconductor chip 10a to a package substrate or another semiconductor chip. The redistribution layer 210a may include, for example, aluminum (Al).

The semiconductor chip 10a of FIG. 3 may include first and second chip guards G1 and G2 in a chip sealing region 12. The first chip guard G1 may be substantially the same as the chip guard G1 of the semiconductor chip 10 described above with reference to FIGS. 2A and 2B.

Referring to FIG. 3, the second chip guard G2 may include the insulating protection structure 190, a barrier trench 201 penetrating the insulating protection structure 190, and a metal barrier layer 210b disposed along at least an inner sidewall of the barrier trench 201.

The barrier trench 201 may be formed to penetrate the insulating protection structure 190 to reach the inside of a third intermetallic insulating layer 173 or an interface between the third intermetallic insulating layer 173 and a third metal capping layer 171. The barrier trench 201 may have a bottom surface 201B and a sidewall surface 201W.

The barrier trench 201 may be formed in a lateral direction (i.e., direction perpendicular to the z-direction) of a fourth metal layer 180, and may be positioned closer to a chip boundary region (13 of FIG. 1) (i.e., farther from the device region 11) than the fourth metal layer 180. Accordingly, an upper guard structure (i.e., the first chip guard G1) including first to fourth metal layers 120, 140, 160, and 180, first to third contact patterns 142, 162, and 182, and first to third barrier patterns 144, 164, 184a and 184b might not disposed directly below the bottom surface 201B of the barrier trench 201.

The bottom surface 201B of the barrier trench 201 may be disposed to be spaced apart from an upper surface 180U of the fourth metal layer 180. The bottom surface 201B of the barrier trench 201 may be positioned lower (i.e., closer to the substrate 101) than the upper surface 180U of the fourth metal layer 180. In an embodiment, although not illustrated, the bottom surface 201B of the barrier trench 201 may be positioned lower (i.e., closer to the substrate 101) than the upper surface 140U of the second metal layer 140.

The metal barrier layer 210b may be disposed on a sidewall surface 201W and the bottom surface 201B of the barrier trench 201, and may also be disposed on the third passivation layer 195 outside the barrier trench 201. A portion of the metal barrier layer 210b disposed on the sidewall surface 201W of the barrier trench 201 may contact the fourth metal layer 180.

The metal barrier layer 210b may include, for example, aluminum (Al). In an embodiment, the metal barrier layer 210b may block moisture inside or outside the chip sealing region 12 from penetrating into the device region 11 via the insulating protection structure 190 and the third interlayer insulating layer 170.

In addition, in an embodiment, the metal layer constituting the first chip guard G1 might not be disposed directly below the bottom surface 201B of the barrier trench 201, so that the first chip guard G1 may be protected from physical damage. As an example of the physical damage, there may be cracks. In an embodiment, the crack may occur at an interface between the sidewall surface 201W of the barrier trench 201 closer to the chip boundary region (13 of FIG. 1) and the insulating protection structure 190. In an embodiment, the crack may propagate to the bottom surface 201B of the barrier trench 201 along the interface, and then proceed directly below the bottom surface 201B of the barrier trench 201. In an embodiment, when the first chip guard G1 is disposed directly below the bottom surface 201B of the barrier trench 201, the structural stability of the first chip guard G1 may be deteriorated as the crack progresses.

As described above, the second chip guard G2 according to an embodiment of the present disclosure may include a barrier trench having a bottom surface that does not overlap with the metal layer inside the first chip guard G1 in a substrate direction, and a metal barrier layer disposed inside the barrier trench. Accordingly, in an embodiment, it is possible to prevent cracks generated in the region adjacent to the barrier trench from propagating to the metal layer inside the first chip guard G1.

In some embodiments, in the semiconductor chip including the first chip guard G1 and the second chip guard G2, apart from that illustrated in FIG. 3, the first chip guard G1 might not include the first to third barrier patterns 144, 164, 184a, and 184b. That is, an upper guard structure of the first chip guard G1 may include a metal structure including the first to fourth metal layers 120, 140, 160, 180, and the first to third contact patterns 142, 162 and 182, except for the first to third barrier patterns 144, 164, 184a, and 184b.

As described above, the chip guard of the semiconductor chip according to various embodiments of the present disclosure may be disposed in the chip sealing region to include at least one of a barrier pattern and a barrier trench, thereby providing an effective chip sealing function for the semiconductor chip.

The concepts have been disclosed in conjunction with some embodiments as described above. Those skilled in the art will appreciate that various modifications, additions and substitutions are possible, without departing from the scope and spirit of the present disclosure. Accordingly, the embodiments disclosed in the present specification should be considered from not a restrictive standpoint but an illustrative standpoint. The scope of the concepts is not limited to the above descriptions but defined by the accompanying claims, and all of distinctive features in the equivalent scope should be construed as being included in the concepts.

What is claimed is:

1. A semiconductor chip comprising:
an integrated circuit disposed in a device region; and
a chip guard disposed in a chip sealing region that is an outer portion of the device region,
wherein the chip guard comprises:
a first metal layer disposed over a substrate;
an interlayer insulating layer disposed on the first metal layer;
a second metal layer disposed on the interlayer insulating layer; and
a barrier pattern extending in a direction towards the substrate from the second metal layer through the interlayer insulating layer, and
wherein the barrier pattern is disposed to be spaced apart from the first metal layer.

2. The semiconductor chip of claim 1, wherein the chip guard further comprises a contact pattern connecting the first and second metal layers.

3. The semiconductor chip of claim 2, wherein the barrier pattern is disposed farther from the device region than the contact pattern.

4. The semiconductor chip of claim 1, wherein a bottom surface of the barrier pattern is disposed closer to the substrate than an upper surface of the first metal layer.

5. The semiconductor chip of claim 1, wherein the bottom surface of the barrier pattern is disposed closer to the substrate than a bottom surface of the first metal layer.

6. The semiconductor chip of claim 1, wherein the interlayer insulating layer comprises:
a metal capping layer covering the upper surface of the first metal layer; and
an intermetallic insulating layer disposed on the metal capping layer.

7. The semiconductor chip of claim 6, wherein the metal capping layer and the intermetallic insulating layer are made of different materials from each other.

8. The semiconductor chip of claim 1, wherein the chip guard comprises:
a first planarization insulating layer surrounding a side surface of the first metal layer; and
a second planarization insulating layer surrounding a side surface of the second metal layer.

9. The semiconductor chip of claim 8, wherein the barrier pattern extends from the second metal layer to reach inside the first planarization insulating layer.

10. The semiconductor chip of claim 1,
wherein the first metal layer comprises one of copper (Cu) and tungsten (W),
wherein the second metal layer comprises one of copper (Cu) and aluminum (Al), and
wherein the barrier pattern comprises one of copper (Cu) and tungsten (W).

11. The semiconductor chip of claim 1, wherein the chip guard further comprises:
a lower metal layer disposed between the first metal layer and the substrate;
a first lower contact pattern connecting the lower metal layer to the substrate; and
a second lower contact pattern connecting the first metal layer to the lower metal layer.

12. The semiconductor chip of claim 1, wherein the chip guard further comprises:
an insulating protection structure disposed over the second metal layer;
a barrier trench passing through the insulating protection structure and formed in a lateral direction of the second metal layer; and
a metal barrier layer disposed on at least a sidewall surface and bottom surface of the barrier trench.

13. The semiconductor chip of claim 12, wherein the bottom surface of the barrier trench is disposed to be spaced apart from an upper surface of the second metal layer.

14. The semiconductor chip of claim 13, wherein the bottom surface of the barrier trench is positioned closer to the substrate than the upper surface of the second metal layer.

15. The semiconductor chip of claim 12, wherein the barrier trench is positioned farther from the device region than the second metal layer.

16. A semiconductor chip comprising:
an integrated circuit disposed in a device region; and
a chip guard disposed in a chip sealing region that is an outer portion of the device region,
wherein the chip guard comprises:
a first metal layer disposed over a substrate;
an interlayer insulating layer disposed on the first metal layer;
a second metal layer disposed on the interlayer insulating layer;
a contact pattern connecting the first and second metal layers to each other in the interlayer insulating layer;
an insulating protection structure disposed on the second metal layer;
a barrier trench penetrating the insulating protection structure and formed in a lateral direction of the second metal layer; and
a metal barrier layer disposed on at least a sidewall surface and bottom surface of the barrier trench, and
wherein a bottom surface of the barrier trench is disposed to be spaced apart from an upper surface of the second metal layer.

17. The semiconductor chip of claim 16, wherein the barrier trench is positioned farther from the device region than the second metal layer.

18. The semiconductor chip of claim 16, wherein the bottom surface of the barrier trench is positioned closer to the substrate than the upper surface of the second metal layer.

19. The semiconductor chip of claim 16, wherein the chip guard further comprises a barrier pattern extending in the direction toward the substrate from the second metal layer through the interlayer insulating layer, and
wherein the barrier pattern is disposed to be spaced apart from the first metal layer.

20. The semiconductor chip of claim 19, wherein the barrier pattern is disposed farther from the device region than the contact pattern.

21. A semiconductor chip comprising:
an integrated circuit disposed in a device region; and
a chip guard disposed in a chip sealing region that is an outer portion of the device region,
wherein the chip guard comprises:
a plurality of metal layers disposed over a substrate;
at least one interlayer insulating layer disposed between the plurality of metal layers; and
a barrier pattern extending toward the substrate from at least one metal layer among the plurality of metal layers, and
wherein the barrier pattern is disposed to be spaced apart from the remaining metal layers, except for the at least one metal layer among the plurality of metal layers, in a lateral direction.

22. The semiconductor chip of claim 21, wherein the barrier pattern is disposed to penetrate the at least one interlayer insulating layer to extend in the substrate direction.

23. The semiconductor chip of claim 21, wherein the chip guard further comprises:
an insulating protection structure disposed over the plurality of metal layers;
a barrier trench penetrating the insulating protection structure to be formed in a lateral direction of the plurality of metal layers; and
a metal barrier layer disposed along at least a sidewall surface of the barrier trench.
